(19) United States
(12) Patent Application Publication
(10) Pub. No.: US 2025/0218898 A1
(43) Pub. Date: Jul. 3, 2025

(54) RECONSTITUTED PASSIVE WITH MECHANICAL SUPPORT STRUCTURES

(71) Applicant: Intel Corporation, Santa Clara, CA (US)

(72) Inventors: Jeremy D. ECTON, Gilbert, AZ (US); Brandon C. MARIN, Gilbert, AZ (US); Srinivas Venkata Ramanuja PIETAMBARAM, Chandler, AZ (US); Gang DUAN, Chandler, AZ (US); Benjamin DUONG, Phoenix, AZ (US)

(21) Appl. No.: 18/398,685

(22) Filed: Dec. 28, 2023

(51) Int. Cl. H01L 23/48; H01L 23/00; H01L 23/13; H01L 23/15; H01L 23/498

(52) U.S. Cl. CPC H01L 23/481; H01L 23/13; H01L 23/15; H01L 23/49816; H01L 24/16; H01L 24/94; H01L 2224/16225; H01L 2224/94; H01L 2924/15311

(57) ABSTRACT

Embodiments disclosed herein include components that include passive electrical devices with a thickness augmentation. In an embodiment, such an apparatus comprises a substrate with a first material composition, and a liner on a sidewall of the substrate. In an embodiment, a layer is on the substrate, where the layer has a second material composition that is different than the first material composition. In an embodiment, the layer directly contacts at least a portion of a surface of the substrate.

### BACKGROUND

As advanced packaging is enabling more aggressive computation capability, high power and high quality power delivery is needed to support all of the overlying chiplets. Accordingly, the ability to embed passive components (e.g., capacitors, inductors, resistors, etc.) into the package substrate will enable improved performance compared to placing the passive components on the land side of the package. Embedding components in the core is beneficial because there is less routing in the core compared to overlying and underlying buildup layers. As such, space within the package substrate is more fully utilized.

However, substrate core thickness is defined by the total package thermomechanical stress level. This required thickness can be significantly different than the thickness of the passive component. For example, in the case of a deep trench capacitor (DTC), the DTC is fabricated on a silicon wafer. The wafer will have a thickness that is potentially hundreds of microns different than the thickness of the core, which can be approximately 1.0 mm or greater. Placing such passive components in deep cavities through the core can be problematic. For example, the passive components may shift or rotate during embedding.

### BRIEF DESCRIPTION OF THE DRAWINGS

FIG. 1 is a cross-sectional illustration of a core with an embedded passive component that has shifted during the embedding process, in accordance with an embodiment.

FIG. 2A is a cross-sectional illustration of a component that includes a substrate that is surrounded by a liner and further includes a dummy structure to increase a thickness of the component, in accordance with an embodiment.

FIG. 2B is a cross-sectional illustration of a component that includes a substrate that is surrounded by a liner and further includes a dummy structure with non-planar sidewalls, in accordance with an embodiment.

FIG. 3A is a cross-sectional illustration of a component that includes a substrate that is surrounded by a liner and further includes dummy pillars to increase a thickness of the component, in accordance with an embodiment.

FIG. 3B is a cross-sectional illustration of a component that includes a substrate that is surrounded by a liner and further includes pillars coupled to vias in the substrate, in accordance with an embodiment.

FIGS. 4A-4F are cross-sectional illustrations depicting a process for embedding a reconstituted component into a core of a package substrate, in accordance with an embodiment.

FIG. 4G is a process flow diagram of a process for embedding a reconstituted component into a core of a package substrate, in accordance with an embodiment.

FIG. 5A is a cross-sectional illustration of a core with a plurality of components with dummy pillars embedded within a cavity, in accordance with an embodiment.

FIG. 5B is a cross-sectional illustration of a core with a plurality of components with different thicknesses embedded within a cavity, in accordance with an embodiment.

FIG. 6A is a cross-sectional illustration of a core with a plurality of cavities, and a component with dummy pillars is provided in each cavity, in accordance with an embodiment.

FIG. 6B is a cross-sectional illustration of a core with a plurality of cavities that are used to house components with different thicknesses, in accordance with an embodiment.

FIG. 7 is a cross-sectional illustration of an electronic system that includes a package substrate with an embedded component with spacers to enable thickness matching with a core of the package substrate, in accordance with an embodiment.

FIG. 8 is a schematic of a computing device built in accordance with an embodiment.

### EMBODIMENTS OF THE PRESENT DISCLOSURE

Described herein are electronic systems, and more particularly, components embedded in a deep cavity with dummy structures, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

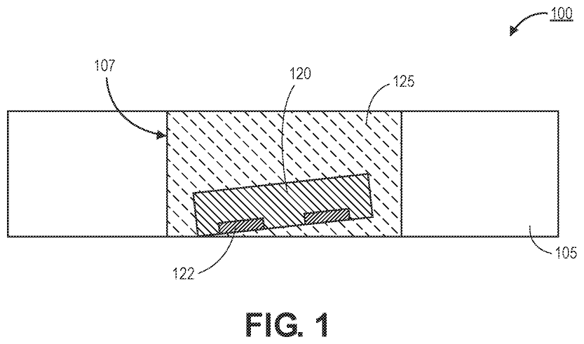

As noted above, introducing passive components (e.g., inductors, capacitors, resistors, etc.) into the package substrate is desirable to improve power delivery and performance for the overlying chiplets compared to placing the passive components on the land side of the package substrate. This is due, at least in part, to the passive components being physically closer to the chiplets when they are integrated into the package substrate. One suitable location in the package substrate for the passive components is the core. The core has underutilized space that can be leveraged to house the passive components. However, the thickness of the passive components is usually smaller than a thickness of the core. This can lead to integration and manufacturing issues. Examples of these drawbacks can be seen in FIG. 1.

Referring now to FIG. 1, a cross-sectional illustration of a portion of a package substrate 100 is shown, in accordance with an embodiment. The package substrate 100 may comprise a core 105. The core 105 may sometimes be referred to simply as a substrate. The core 105 may be a glass core, an organic core, or the like. In an embodiment, a cavity 107 passes at least partially through the core 105. For example, in FIG. 1 the cavity 107 passes entirely through the core 105.

In an embodiment, a component 120 is provided in the cavity 107. The component 120 may have a thickness that is smaller than a thickness of the core 105. For example, the component 120 may have a thickness that is hundreds of microns thinner than the core 105. The component 120 is secured within the cavity 107 through the use of a fill layer 125. The fill layer 125 may be a dielectric material, such as a mold layer, an epoxy, an adhesive, or the like. However, during the filling process, the component 120 may shift and/or rotate. The movement of the component 120 may be due, at least in part, to the introduction of pressure to the component 120 during the filling process. As shown, the component 120 has tilted so that one side is raised up from the bottom of the core 105. This may make it difficult to make electrical contact to the pads 122 that are at the bottom of the component 120 in subsequent processing operations.

Accordingly, embodiments disclosed herein reduce movement of the component 120 by providing components 120 that have a dummy structure (sometimes referred to as a spacer, a layer, a pillar, a support structure, or the like). The dummy structure is provided over the component 120 in order to substantially equalize the thickness of the component with the thickness of the core 105. Individually forming and attaching dummy structures to components 120 may be impracticable in some instances. As such, embodiments disclosed herein may include assembling a plurality of components 120 together in a reconstituted substrate. That is, a plurality of individual components 120 can be overmolded to form a single substrate. The dummy structure can then be manufactured over all components at substantially the same time. The dummy structures may be formed with a plating process, such as a blanket plating process. Alternatively, a semi-additive process (SAP) may be used to form the dummy structures. Etching processes may also be used in some embodiments.

In addition to providing thickness adjustments to the components 120, the dummy structures may also provide additional benefits. In one instance, dummy pillars can be coupled to pads and vias within the component 120. As such, the dummy pillars may actually be part of the electrical circuitry of the device. Dummy structures may also be used to improve thermal performance. For example, when a material with a high thermal conductivity (e.g., copper) is used for the dummy structure, more thermal energy can be withdrawn from the component 120 during operation.

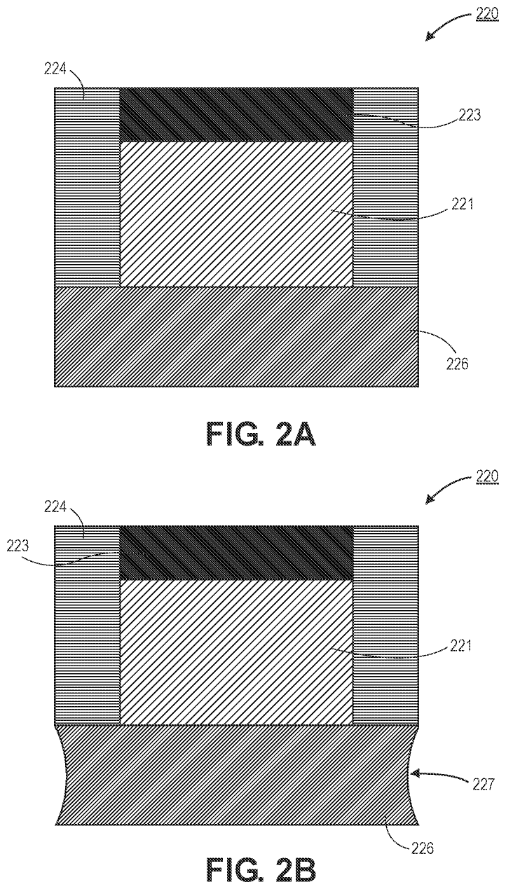

Referring now to FIG. 2A, a cross-sectional illustration of a component 220 is shown, in accordance with an embodiment. In an embodiment, the component 220 may be an electrically passive component. That is, the component 220 may include one or more of an inductor, a capacitor, a resistor, or the like. In a particular embodiment, the component 220 may be a deep trench capacitor (DTC). In the Figures described herein, the component 220 is shown as simple layers, liners, structures (e.g., dummy structures), and the like. The electrical routing (e.g., traces, pads, plates, electrodes), insulators, dielectrics (e.g., high-k dielectrics for capacitors), magnetic material (e.g., for inductors), and/or the like are omitted for simplicity. However, it is to be appreciated that components 220 may include any structures that enable functionality of various passive components.

In an embodiment, the component 220 may comprise a substrate 221. The substrate 221 may include any suitable material that provides a solid base on which (or into which) passive structures can be fabricated. In some embodiments, the substrate 221 may comprise a semiconductor material, such as silicon. For example, a silicon wafer may be processed to produce a plurality of passive devices. After processing, the silicon wafer is singulated in order to provide individual components 220. While silicon can be used in some embodiments, other embodiments may include a substrate 221 that comprises a ceramic, a glass, an insulator, or the like.

In an embodiment a routing layer 223 may be provided over the substrate 221. The routing layer 223 may be a different material than the substrate 221. For example, the routing layer 223 may include a dielectric material, such as one comprising silicon and oxygen (e.g., SiO₂) or silicon and nitrogen (e.g., Si₃N₄). Organic dielectrics may also be used in some embodiments. The routing layer 223 may include electrical routing (not shown), such as pads, traces, and the like. In some embodiments, the routing layer 223 is omitted, or the electrical routing is otherwise provided in the substrate 221.

In an embodiment, a liner 224 is provided along a sidewall of the substrate 221. The liner 224 may be provided around a perimeter of the substrate 221. That is, all sidewalls of substrate 221 may be contacted by the liner 224. In a particular embodiment, the liner 224 covers the entire height of the sidewall of the substrate 221. The liner 224 may also contact the routing layer 223. That is, a height of the liner 224 may be substantially equal to a combined height of the substrate 221 and the routing layer 223. As used herein, “substantially equal” may refer to two values that are within ten percent of each other. For example, liner 224 with a height between 450 μm and 550 μm may be considered as being substantially equal to a combined height of the substrate 221 and the routing layer 223 that is 500 μm. The liner 224 may comprise a molding material. For example, an organic dielectric material, such as an epoxy, a polymer, or the like, may be used for the liner 224. The liner 224 may include filler particles that allow for tailoring a coefficient of thermal expansion (CTE) of the liner 224. This allows for improved CTE matching with the substrate 221 in order to limit warpage, stress generation, or the like.

In an embodiment, a dummy structure 226 is provided on the substrate 221. The dummy structure 226 may be provided in direct contact with the substrate 221. The dummy structure 226 may also directly contact the liner 224. That is, a width of the dummy structure 226 may be greater than a width of the substrate 221 in some embodiments. In an embodiment, the dummy structure 226 may comprise any suitable material or materials, such as one that is rigid and includes a CTE comparable to that of the substrate 221. In an embodiment, the dummy structure 226 may comprise copper or another metallic material. The dummy structure 226 may also include epoxies, polymers, ceramics, glass, or the like. The dummy structure 226 may be disposed over the substrate 221 with any suitable process. For example, a plating process or other deposition process, such as chemical vapor deposition (CVD), physical vapor deposition (PVD), or the like may be used.

In an embodiment, the component 220 may have a total thickness that is substantially equal to a thickness of the core (not shown) in which the component 220 will be embedded. For example, the component 220 may have a total thickness that is approximately 1.0 mm or greater. In the illustrated embodiment, the substrate 221 is thicker than the dummy structure 226. Though, in other embodiments the dummy structure 226 may be thicker than the substrate 221.

Referring now to FIG. 2B, a cross-sectional illustration of a component 220 is shown, in accordance with an additional embodiment. In an embodiment, the component 220 in FIG. 2B is similar to the component 220 in FIG. 2A, with the exception of the dummy structure 226. In FIG. 2A, the dummy structure 226 has substantially vertical sidewalls. However, in FIG. 2B the sidewalls 227 of the dummy structure 226 are non-planar. For example, the sidewalls 227 may be curved. The curvature of the sidewalls 227 may be a result of the singulation process used to isolate the component 220 from a larger reconstituted substrate (not shown).

In some embodiments, dicing through the dummy structure 226 is not practical. As such, an etching process may be used in order to create gaps between dummy structures 226 on the reconstituted substrate. The etching process may be an isotropic etching process (e.g., a wet etch). As such, the sidewalls 227 may have some degree of curvature, or the sidewalls 227 may be sloped. That is, the sidewalls 227 may have a non-vertical profile. It is to be appreciated that the profile of the sidewalls 227 shown in FIG. 2B is exemplary in nature, and that the sidewalls 227 may have any non-vertical profile, depending on the particular etching process used.

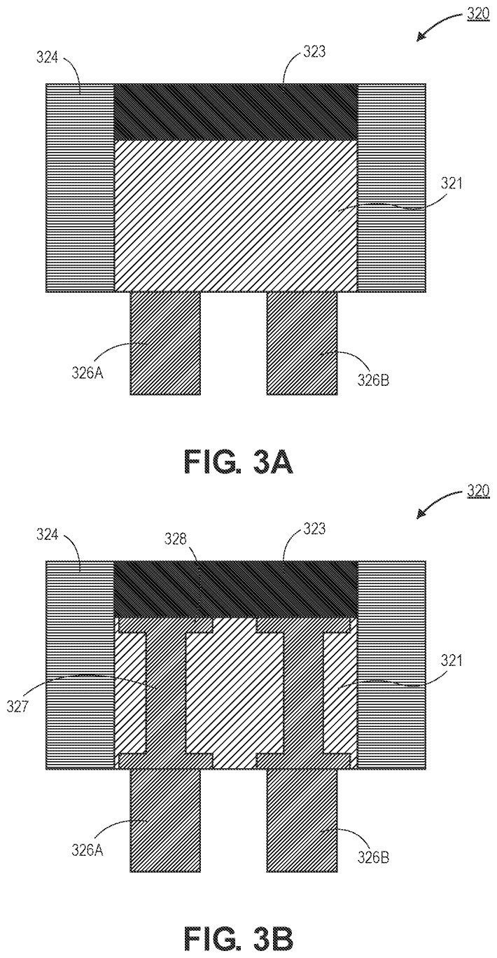

Referring now to FIG. 3A, a cross-sectional illustration of a component 320 is shown, in accordance with an additional embodiment. In an embodiment, the component 320 may be an electrically passive component. That is, the component 320 may include one or more of an inductor, a capacitor, a resistor, or the like. In a particular embodiment, the component 320 may be DTC. In the Figures described herein, the component 320 is shown as simple layers, liners, structures (e.g., dummy structures), and the like. The electrical routing (e.g., traces, pads, plates, electrodes), insulators, dielectrics (e.g., high-k dielectrics for capacitors), magnetic material (e.g., for inductors), and the like are omitted for simplicity. However, it is to be appreciated that components 320 may include any structures that enable functionality of various passive components.

Similar to the embodiment shown in FIG. 2A, the component 320 may comprise a substrate 321, a routing layer 323, and a liner 324. The substrate 321 may be similar to substrate 221, the routing layer 323 may be similar to routing layer 223, and the liner 324 may be similar to liner 224. Component 320 differs from component 220 with respect to the dummy structure 326.

Instead of providing a solid bock or layer over the substrate 321, the dummy layer comprises one or more dummy pillars 326. For example, a first dummy pillar 326A and a second dummy pillar 326B are shown in FIG. 3A. While two dummy pillars 326 are shown, it is to be appreciated that more than two dummy pillars 326 may be used in other embodiments. For example, four dummy pillars 326 may be used in order to provide a more solid base for the component 320.

In an embodiment, the dummy pillars 326A and 326B may comprise a material similar to the material used for the dummy structure 226 described above. For example, the dummy pillars 326A and 326B may comprise copper or the like. In an embodiment, the dummy pillars 326A and 326B may be formed with any suitable patterning or deposition process. In one embodiment, a solid layer (similar to dummy structure 226) may be formed, and the solid layer may then be etched to form the dummy pillars 326A and 326B. In other embodiments, an SAP operation may be used to form the dummy pillars 326A and 326B.

The dummy pillars 326A and 326B may have any suitable dimensions. For example, an aspect ratio (e.g., height:width) may be approximately 0.5:1 or greater, 1:1 or greater, or 5:1 or greater. Though, smaller aspect ratios may also be used in some embodiments. Typically, an SAP process can form higher aspect ratio feature compared to an etching process. Though, etching processes may be more cost effective.

The use of dummy pillars 326A and 326B may provide several benefits for the components 320. For example, reducing the volume of the dummy structure can decrease warpage. That is, warpage due to CTE mismatch is reduced since there is less copper (or other material) directly interfacing with the substrate 321. Additionally, the configuration of the dummy pillars 326A and 326B may provide direct access to the liner 324. As such, singulation of the reconstituted substrate is made easier since the singulation or dicing does not need to pass through copper (or other material of the dummy pillars 326A and 326B).

Referring now to FIG. 3B, a cross-sectional illustration of a component 320 is shown, in accordance with an additional embodiment. The component 320 in FIG. 3B may be similar to the component 320 in FIG. 3A, with the exception of the construction of the substrate 321. For example, the substrate 321 may further comprise vias 327. The vias 327 may be electrically conductive structures that pass through at least a portion of a thickness of the substrate 321. The vias 327 may couple pads 328 at a bottom of the substrate 321 to pads 328 at a top of the substrate 321.

Additionally, the dummy pillars 326A and 326B may be electrically coupled to the vias 327 through pads 328. Though, the dummy pillars 326A and 326B may also be directly coupled to the vias 327 in other embodiments. As such, electricity (e.g., electrical signals, power, etc.) may pass up through the dummy pillars 326A and 326B in order to pass electricity through at least a portion of a thickness of the substrate 321. That is, while referred to as being a “dummy” structure, the dummy pillars 326A and 326B may actually be part of the electrical circuitry of the component 320. This allows for a multi-functionality approach which can lead to improved performance, decreased footprints, and/or other benefits.

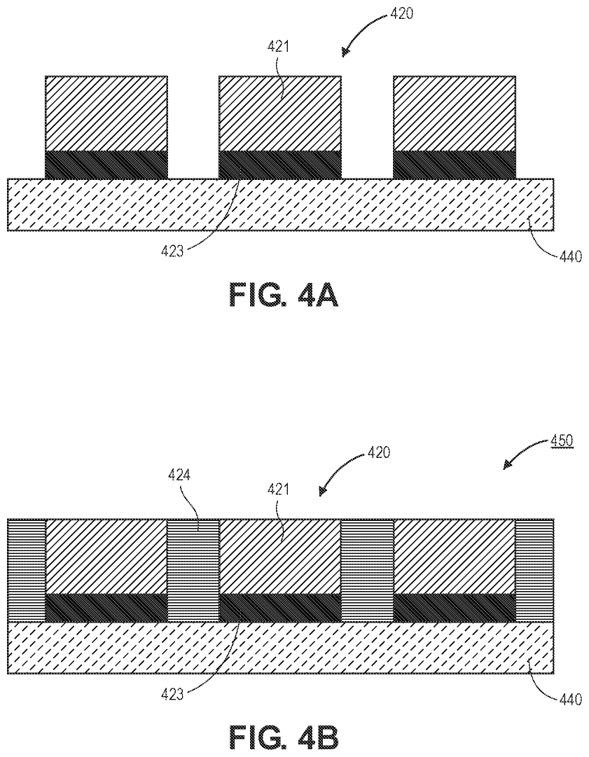

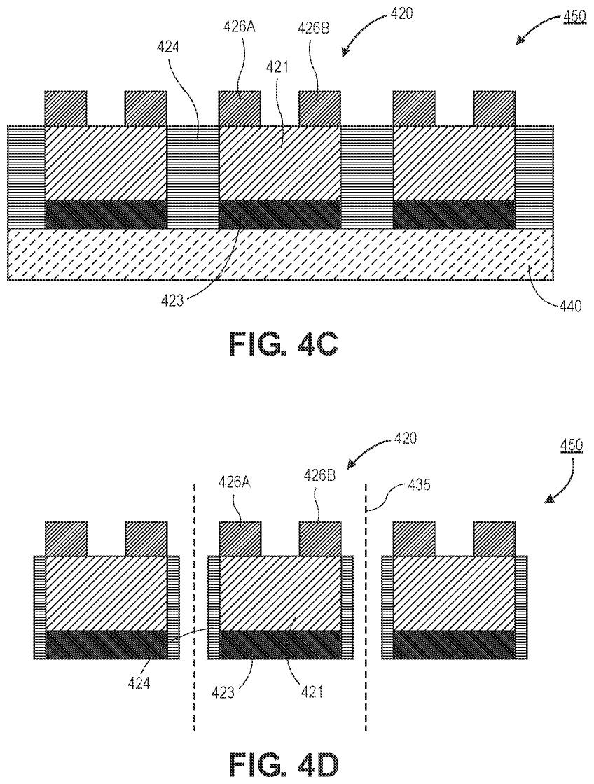

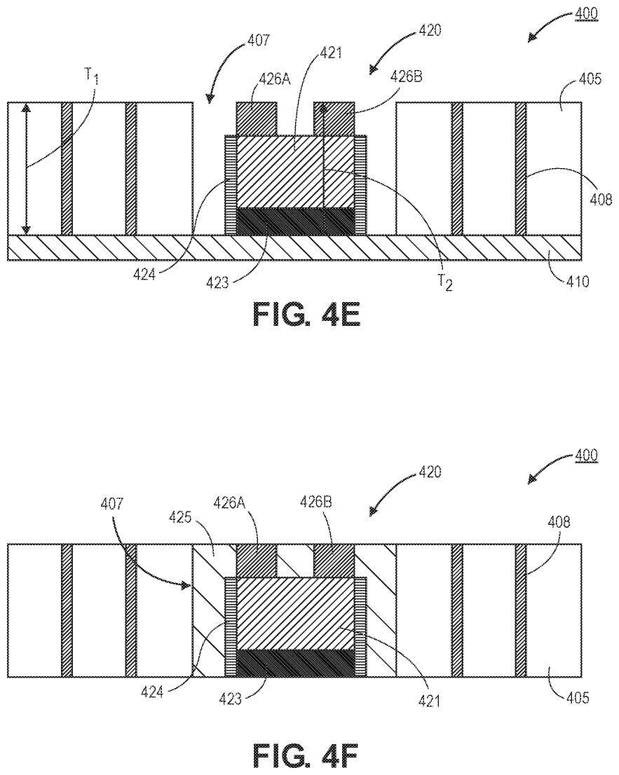

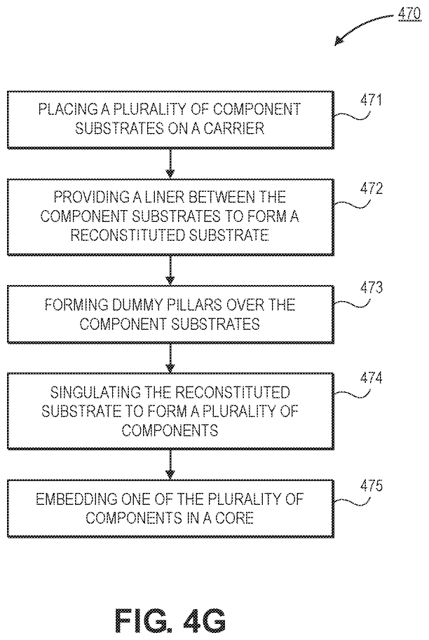

Referring now to FIGS. 4A-4F, a series of cross-sectional illustrations depicting a process for integrating a component 420 into a core 405 of a package substrate 400 is shown, in accordance with an embodiment. In the process described herein, the component 420 is first integrated into a reconstituted substrate 450. The reconstituted substrate can then be processed and singulated. The singulated components 420 are embedded in the core 405.

Referring now to FIG. 4A, a cross-sectional illustration of a plurality of components 420 is shown, in accordance with an embodiment. The components 420 may be similar to any of the components described in greater detail herein. For example, the components 420 may be passive components comprising one or more of a capacitor, an inductor, a resistor, or the like. More particularly, a passive component may comprise a DTC or a metal-insulator-metal (MIM) capacitor. In an embodiment, the components 420 may comprise a substrate 421 and a routing layer 423. The substrate 421 may comprise a semiconductor, such as silicon, or any other suitable material. The routing layer 423 may include a dielectric with embedded electrical routing or the like.

In an embodiment, the components 420 are placed on a carrier substrate 440. The carrier substrate 440 may comprise glass, silicon, metal, ceramic, or the like. The carrier substrate 440 is a temporary structure used to support the components 420 during the generation of the reconstituted substrate 450 shown in a subsequent processing operation. In an embodiment, the components 420 may be oriented so that the routing layers 423 are contacting the carrier substrate 440. Though, the routing layers 423 may also face away from the carrier substrate 440 in other embodiments.

Referring now to FIG. 4B, a cross-sectional illustration of a reconstituted substrate 450 is shown, in accordance with an embodiment. The reconstituted substrate 450 may be formed with a molding process in some embodiments. The molding process may include molding a liner 424 between the components 420. The liner 424 may be an epoxy or other polymer compatible with molding operations. While molding is provided as one embodiment, other liner deposition processes may also be used.

In an embodiment, the liner 424 may be formed to a thickness that is greater than a thickness of the components 420. After molding, a polishing or planarizing process (e.g. chemical mechanical planarization (CMP)) may be used in order to recess the liner 424. The recessing may result in a top surface of the liner 424 being substantially coplanar with a top surface of the substrate 421.

Referring now to FIG. 4C, a cross-sectional illustration of the reconstituted substrate 450 after dummy pillars 426A and 426B are formed on the components 420 is shown, in accordance with an embodiment. In an embodiment, the dummy pillars 426A and 426B are formed with any suitable deposition process. In one embodiment, a blanket layer is deposited over the top surfaces of the liner 424 and the substrates 421. The blanket layer can then be patterned to form the dummy pillars 426A and 426B with an etching process or the like. In another embodiment, an SAP operation may be used in order to plate up the dummy pillars 426A and 426B. The use of an SAP to form the dummy pillars 426A and 426B may allow for higher aspect ratios (e.g., 5:1 or larger).

In the illustrated embodiment, two dummy pillars 426A and 426B are shown on each component 420. Though, fewer or more dummy pillars 426 may be provided on each component 420. Further, a single dummy structure or layer (e.g., similar to dummy structure 226 in FIG. 2A) may be used instead of dummy pillars 426A and 426B. Embodiments may also include vias (not shown) through the substrate 421 that are electrically coupled to the dummy pillars 426A and 426B.

Referring now to FIG. 4D, a cross-sectional illustration of the reconstituted substrate 450 after the carrier substrate 440 is removed, and the reconstituted substrate 450 is singulated is shown, in accordance with an embodiment. As shown, singulation of individual components 420 may be made by slicing through the liner 424 along lines 435. The singulation may be done with a mechanical process (e.g., sawing), a laser ablation process, an etching process, or the like. When dummy pillars 426A and 426B are used instead of a continuous layer, the lines 435 may not pass through copper (or other dummy material). As such, the singulation process may be simplified since only a single material needs to be diced and/or cut.

In the illustrated embodiment, the resulting sidewalls of the liner 424 are substantially vertical. Though, different dicing methods may result in sidewalls that have profiles that are non-vertical and/or non-planar. While the dicing is shown in one direction (i.e., along each side of the components 420), it is to be appreciated that dicing also occurs in front of the components 420 and behind the components (as viewed in FIG. 4D). As such, the liner 424 may wrap entirely around a perimeter of the substrate 421 and/or the routing layer 423. Further, a height of the liner 424 may be substantially equal to the combined height of the substrate 421 and the routing layer 423.

Referring now to FIG. 4E, a cross-sectional illustration of a portion of a package substrate 400 is shown, in accordance with an embodiment. Particularly, a portion of the core 405 is shown in FIG. 4E. The core 405 may be a glass core 405, an organic core 405, or any other type of material. In the case of a glass core 405, the glass core 405 may be substantially all glass. The glass core 405 may be a solid mass comprising a glass material with an amorphous crystal structure where the solid glass core may also include various structures-such as vias, cavities, channels, or other features-that are filled with one or more other materials (e.g., metals, metal alloys, dielectric materials, etc.). As such, glass core 405 may be distinguished from, for example, the “prepreg” or “RF4” core of a Printed Circuit Board (PCB) substrate which typically comprises glass fibers embedded in a resinous organic material, such as an epoxy.

The glass core 405 may have any suitable dimensions. In a particular embodiment, the glass core 405 may have a thickness that is approximately 50 μm or greater. For example, the thickness of the glass core 405 may be between approximately 50 μm and approximately 1.4 mm. Though, smaller or larger thicknesses may also be used. The glass core 405 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 405 (from an overhead plan view) may be between approximately 10 mm×10 mm and approximately 250 mm×250 mm. In an embodiment, the glass core 405 may have a first side that is perpendicular or orthogonal to a second side. In a more general embodiment, the glass core 405 may comprise a rectangular prism volume with sections (e.g., vias) removed and filled with other materials (e.g., metal, etc.).

The glass core 405 may comprise a single monolithic layer of glass. In other embodiments, the glass core 405 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 405 may each have a thickness less than approximately 50 μm. For example, discrete layers of glass in the glass core 405 may have thicknesses between approximately 25 μm and approximately 50 μm. Though, discrete layers of glass may have larger or smaller thicknesses in some embodiments.

The glass core 405 may be any suitable glass formulation that has the necessary mechanical robustness and compatibility with semiconductor packaging manufacturing and assembly processes. For example, the glass core 405 may comprise aluminosilicate glass, borosilicate glass, alumino-borosilicate glass, silica, fused silica, or the like. In some embodiments, the glass core 405 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 405 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 405 may comprise at least 23 percent silicon (by weight) and at least 26 percent oxygen (by weight). In some embodiments, the glass core 405 may further comprise at least 5 percent aluminum (by weight).

In an embodiment, one or more vias 408 may pass through a thickness of the core 405. In the illustrated embodiment, the vias 408 have a rectangular cross-section. Though, other embodiments may include vias 408 with tapered sidewalls. In some embodiments, an insulating plug (not shown) may be provided inside the vias 408.

In an embodiment, a cavity 407 may pass through at least a portion of a thickness of the core 405. In the illustrated embodiment, the cavity 407 passes entirely through the core 405. Sidewalls of the cavity 407 may be substantially vertical. Other embodiments may include sidewalls that are sloped, tapered, or the like.

In an embodiment, a carrier or tape 410 may be provided below the core 405. The tape 410 may span the opening of the cavity 407 in order to provide a support surface for the component 420. In an embodiment, the component 420 may be placed into the cavity 407 with a pick-and-place tool, manually, or with any other suitable process. In an embodiment, component 420 is placed onto the tape 410 so that the routing layer 423 contacts the tape 410. In an embodiment, the core 405 may have a first thickness T₁, and the component 420 may have a second thickness T₂. The first thickness T₁ may be substantially equal to the second thickness T₂.

Referring now to FIG. 4F, a cross-sectional illustration of the portion of the package substrate 400 after the component 420 is embedded in the cavity 407 is shown, in accordance with an embodiment. The component 420 may be embedded by a layer 425. The layer 425 may be a buildup film or any other suitable dielectric material. In some embodiments, the layer 425 may be a different material than the liner 424. Though, in other embodiments, the liner 424 and the layer 425 may be the same material or a similar material. After the layer 425 is applied, the tape 410 may be removed. Routing layers (not shown) above and below the core 405 can then be added using conventional buildup layer processing techniques.

Referring now to FIG. 4G, a process flow diagram of a process 470 for forming components from a reconstituted substrate and embedding the component in a core is shown, in accordance with an embodiment. In an embodiment, the process 470 may begin with operation 471, which comprises placing a plurality of component substrates on a carrier. The operation 471 may include a structure and process similar to what is illustrated and described with respect to FIG. 4A.

In an embodiment, the process 470 may continue with operation 472, which comprises providing a liner between the component substrates to form a reconstituted substrate. The operation 472 may include a structure and process similar to what is illustrated and described with respect to FIG. 4B.

In an embodiment, the process 470 may continue with operation 473, which comprises forming dummy pillars over the component substrate. The operation 473 may include a structure and process similar to what is illustrated and described with respect to FIG. 4C.

In an embodiment, the process 470 may continue with operation 474, which comprises singulating the reconstituted substrate to form a plurality of components. The operation 474 may include a structure and process similar to what is illustrated and described with respect to FIG. 4D.

In an embodiment, the process 470 may continue with operation 475, which comprises embedding one of the plurality of components in a core. The operation 475 may include a structure and process similar to what is illustrated and described with respect to FIG. 4E and/or FIG. 4F.

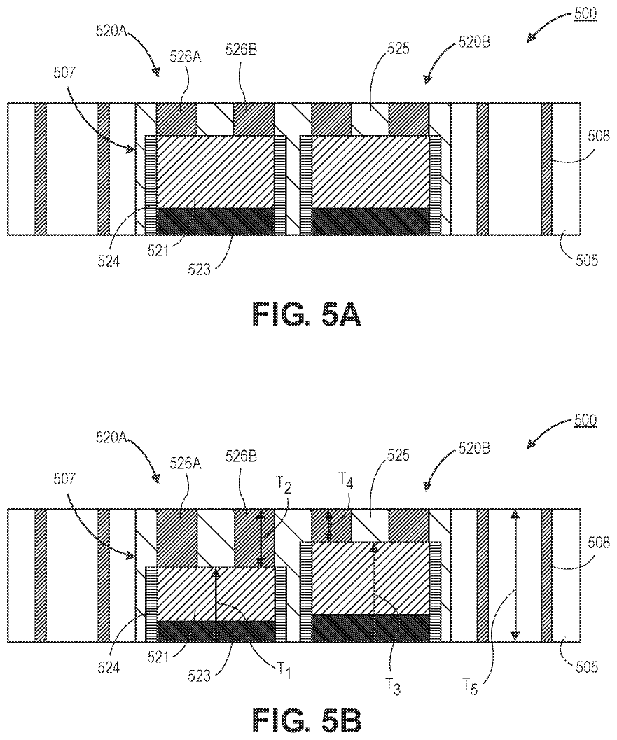

Referring now to FIG. 5A, a cross-sectional illustration of a portion of a package substrate 500 is shown, in accordance with an additional embodiment. In an embodiment, the package substrate 500 may comprise a core 505, such as a glass core 505 or an organic core 505. The core 505 may be similar to other cores described in greater detail herein. In an embodiment, vias 508 may pass through the core 505.

In an embodiment, a cavity 507 may be provided through a thickness of the core 505. A plurality of components 520 may be embedded in the cavity 507 by a layer 525. For example, a first component 520A and a second component 520B are shown in FIG. 5A. The first component 520A and the second component 520B may be substantially similar to each other. For example, both may include a substrate 521 with a routing layer 523. Liners 524 may surround both components 520A and 520B. Additionally, dummy pillars 526A and 526B may be provided over the substrate 521 for each component 520.

Referring now to FIG. 5B, a cross-sectional illustration of a portion of an electronic package 500 is shown, in accordance with an additional embodiment. The electronic package 500 in FIG. 5B may be similar to the electronic package 500 in FIG. 5A, with the exception of the structure of the first component 520A and the second component 520B. The first component 520A may include a first thickness T₁ for the substrate 521 and the routing layer 523 and a second thickness T₂ for the dummy pillars 526A and 526B. The second component 520B may include a third thickness T₃ for the substrate 521 and the routing layer 523 and a fourth thickness T₄ for the dummy pillars 526A and 526B. The combined thickness of the first component 520A (i.e., T₁+T₂) may be substantially equal to the combined thickness of the second component 520B (i.e., T₃+T₄). Both combined thicknesses may be substantially similar to a fifth thickness T₅ of the core 505.

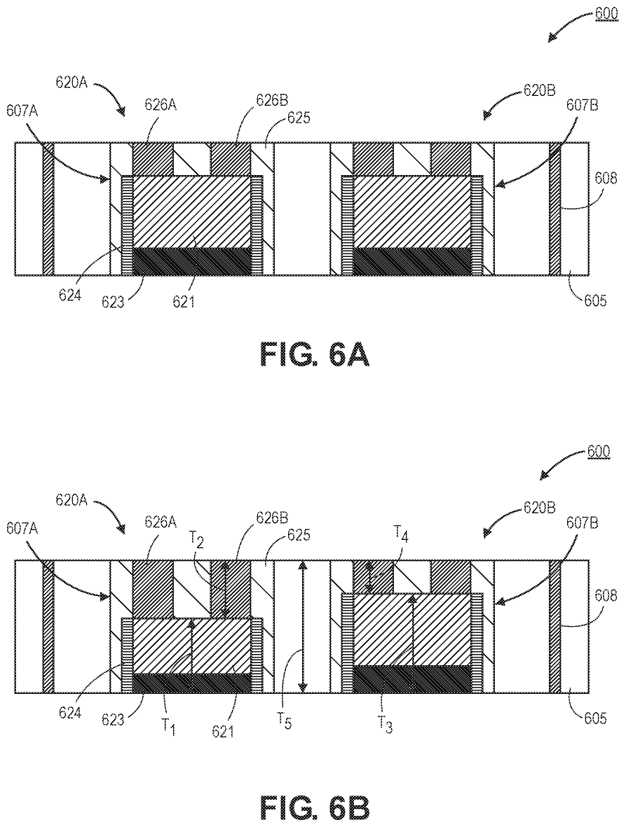

Referring now to FIG. 6A, a cross-sectional illustration of a portion of a package substrate 600 is shown, in accordance with an additional embodiment. In an embodiment, the package substrate 600 may comprise a core 605, such as a glass core 605 or an organic core 605. The core 605 may be similar to other cores described in greater detail herein. In an embodiment, vias 608 may pass through the core 605.

In an embodiment, a first cavity 607A and a second cavity 607B may be provided through a thickness of the core 605. A components 620A or 620B may be embedded in each of the cavities 607A and 607B by a layer 625. For example, a first component 620A may be provided in the first cavity 607A, and a second component 620B may be provided in the second cavity 607B. The first component 620A and the second component 620B may be substantially similar to each other. For example, both may include a substrate 621 with a routing layer 623. Liners 624 may surround both components 620A and 620B. Additionally, dummy pillars 626A and 626B may be provided over the substrate 621 for each component 620.

Referring now to FIG. 6B, a cross-sectional illustration of a portion of an electronic package 600 is shown, in accordance with an additional embodiment. The electronic package 600 in FIG. 6B may be similar to the electronic package 600 in FIG. 6A, with the exception of the structure of the first component 620A and the second component 620B. The first component 620A may include a first thickness T₁ for the substrate 621 and the routing layer 623 and a second thickness T₂ for the dummy pillars 626A and 626B. The second component 620B may include a third thickness T₃ for the substrate 621 and the routing layer 623 and a fourth thickness T₄ for the dummy pillars 626A and 626B. The combined thickness of the first component 620A (i.e., T₁+T₂) may be substantially equal to the combined thickness of the second component 620B (i.e., T₃+T₄). Both combined thicknesses may be substantially similar to a fifth thickness T₅ of the core 605.

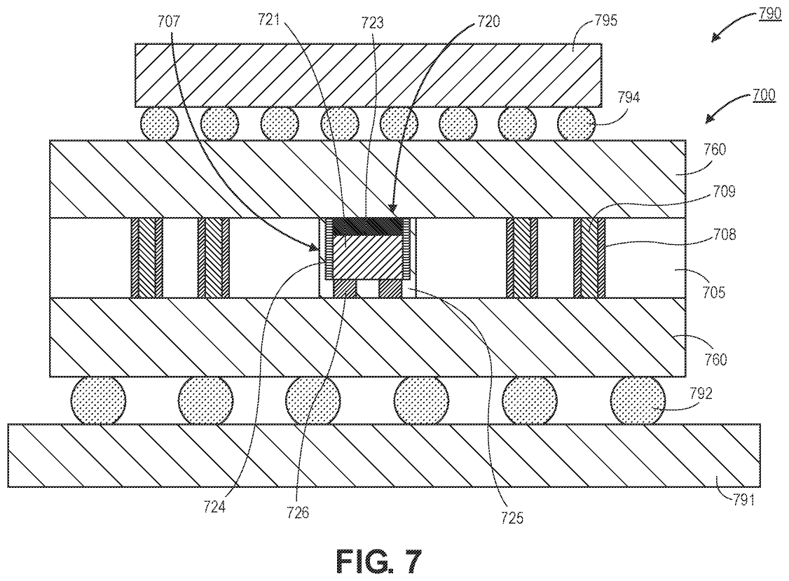

Referring now to FIG. 7, a cross-sectional illustration of an electronic system 790 is shown, in accordance with an embodiment. In an embodiment, the electronic system 790 comprises a board, such as a printed circuit board (PCB), a motherboard, or the like. In an embodiment, the board 790 is coupled to a package substrate 700 by interconnects 792. The interconnects 792 may be second level interconnects (SLIs), such as solder balls, sockets, pins, or the like.

In an embodiment, the package substrate 700 may be similar to any of the package substrates described herein. For example, the package substrate 700 may include a core 705 (e.g., a glass core 705 or an organic core 705) with buildup layers 760 above and below the core 705. The core 705 may comprise vias 708. In FIG. 7, the vias 708 are filled with an insulating plug 709. A cavity 707 may be provided through a thickness of the core 705. A component 720 may be embedded in a layer 725 that fills the cavity 707.

In an embodiment, the component 720 may be similar to any of the components described in greater detail herein. For example, the component 720 may be a passive component such as one or more of an inductor, a capacitor, a resistor, or the like. The component 720 may have a total thickness that is substantially equal to a thickness of the core 705. In an embodiment, the component 720 may comprise a substrate 721 and a routing layer 723, both of which may be surrounded by a liner 724. Dummy pillars 726 (or other spacer or standoff structures) may be provided on the substrate 721 to increase the thickness of the component 720.

In an embodiment, one or more dies 795 may be coupled to the package substrate 700 by interconnects 794. The interconnects 794 may comprise first level interconnects (FLIs), such as solder balls, copper bumps, hybrid bonding interfaces, or the like. The die 795 may be any type of die, such as a central processing unit (CPU), a graphics processing unit (GPU), an XPU, a communications die, a memory die, an application specific integrated circuit (ASIC), a field programmable gate array (FPGA), or the like. In an embodiment, the component 720 is electrically coupled to the one or more dies 795 in order to control and/or improve power delivery that is provided to the die 795.

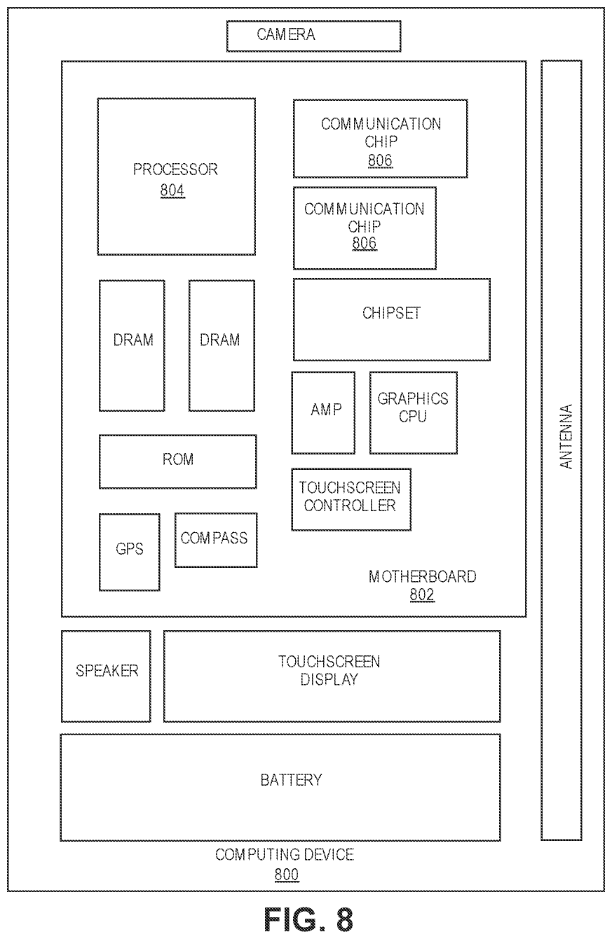

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that includes a component with dummy pillars or other spacer structures that are embedded in a cavity that passes through a core of the package substrate, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that includes a component with dummy pillars or other spacer structures that are embedded in a cavity that passes through a core of the package substrate, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate with a first material composition; a liner on a sidewall of the substrate; and a layer on the substrate, wherein the layer has a second material composition that is different than the first material composition, and wherein the layer directly contacts at least a portion of a surface of the substrate.

Example 2: the apparatus of Example 1, wherein the layer directly contacts the liner.

Example 3: the apparatus of Example 1 or Example 2, wherein the liner surrounds an entire perimeter of the first layer.

Example 4: the apparatus of Examples 1-3, wherein the layer comprises a first pillar and a second pillar.

Example 5: the apparatus of Example 4, wherein the substrate comprises a via, and wherein the first pillar or the second pillar is electrically coupled to the via.

Example 6: the apparatus of Examples 1-5, wherein the substrate comprises silicon, and wherein the layer comprises copper.

Example 7: the apparatus of Examples 1-6, wherein the substrate comprises a passive component including one or more of a capacitor, an inductor, or a resistor.

Example 8: the apparatus of Examples 1-7, wherein a sidewall of the layer is non-planar.

Example 9: the apparatus of Examples 1-8, wherein the substrate comprises: a first portion comprising a semiconductor material; and a second portion comprising electrical routing embedded in a dielectric layer.

Example 10: the apparatus of Example 9, wherein the liner covers the first portion and the second portion.

Example 11: an apparatus, comprising: a first substrate with a first thickness; a cavity through the first substrate; a component in the cavity, wherein the component has a second thickness that is substantially equal to the first thickness, and wherein the component comprises: a second substrate; a liner around a perimeter of the second substrate; and a first layer on the second substrate; and a second layer in the cavity around the component.

Example 12: the apparatus of Example 11, wherein the component comprises one or more of an inductor, a capacitor, or a resistor.

Example 13: the apparatus of Example 11 or Example 12, wherein the first layer comprises a first pillar and a second pillar.

Example 14: the apparatus of Examples 11-13, wherein the liner comprises a first material composition, and wherein the second layer comprises a second material composition that is different than the first material composition.

Example 15: the apparatus of Examples 11-14, wherein the second substrate comprises silicon.

Example 16: the apparatus of Examples 11-15, wherein the first layer comprises copper.

Example 17: the apparatus of Examples 11-16, wherein the first substrate comprises a solid glass layer with a rectangular prism form factor or an epoxy layer.

Example 18: an apparatus, comprising: a board; a package substrate coupled to the board, wherein the package substrate comprises: a core with a cavity through the core; a component in the cavity; and a spacer on the component, wherein a combined thickness of the spacer and the component is substantially equal to a thickness of the core; and a die coupled to the package substrate.

Example 19: the apparatus of Example 18, wherein the component comprises a liner around a semiconductor substrate, wherein the liner comprises a dielectric, a mold material, or a polymer.

Example 20: the apparatus of Example 18 or Example 19, wherein the apparatus is part of a personal computer, a server, a mobile device, a tablet, or an automobile.

What is claimed is:

1. An apparatus, comprising:
a substrate with a first material composition;
a liner on a sidewall of the substrate; and
a layer on the substrate, wherein the layer has a second material composition that is different than the first material composition, and wherein the layer directly contacts at least a portion of a surface of the substrate.

2. The apparatus of claim 1, wherein the layer directly contacts the liner.

3. The apparatus of claim 1, wherein the liner surrounds an entire perimeter of the first layer.

4. The apparatus of claim 1, wherein the layer comprises a first pillar and a second pillar.

5. The apparatus of claim 4, wherein the substrate comprises a via, and wherein the first pillar or the second pillar is electrically coupled to the via.

6. The apparatus of claim 1, wherein the substrate comprises silicon, and wherein the layer comprises copper.

7. The apparatus of claim 1, wherein the substrate comprises a passive component including one or more of a capacitor, an inductor, or a resistor.

8. The apparatus of claim 1, wherein a sidewall of the layer is non-planar.

9. The apparatus of claim 1, wherein the substrate comprises:
a first portion comprising a semiconductor material; and
a second portion comprising electrical routing embedded in a dielectric layer.

10. The apparatus of claim 9, wherein the liner covers the first portion and the second portion.

11. An apparatus, comprising:
a first substrate with a first thickness;
a cavity through the first substrate;
a component in the cavity, wherein the component has a second thickness that is substantially equal to the first thickness, and wherein the component comprises:
a second substrate;
a liner around a perimeter of the second substrate; and
a first layer on the second substrate; and
a second layer in the cavity around the component.

12. The apparatus of claim 11, wherein the component comprises one or more of an inductor, a capacitor, or a resistor.

13. The apparatus of claim 11, wherein the first layer comprises a first pillar and a second pillar.

14. The apparatus of claim 11, wherein the liner comprises a first material composition, and wherein the second layer comprises a second material composition that is different than the first material composition.

15. The apparatus of claim 11, wherein the second substrate comprises silicon.

16. The apparatus of claim 11, wherein the first layer comprises copper.

17. The apparatus of claim 11, wherein the first substrate comprises a solid glass layer with a rectangular prism form factor or an epoxy layer.

18. An apparatus, comprising:
a board;
a package substrate coupled to the board, wherein the package substrate comprises:
a core with a cavity through the core;
a component in the cavity; and
a spacer on the component, wherein a combined thickness of the spacer and the component is substantially equal to a thickness of the core; and
a die coupled to the package substrate.

19. The apparatus of claim 18, wherein the component comprises a liner around a semiconductor substrate, wherein the liner comprises a dielectric, a mold material, or a polymer.

20. The apparatus of claim 18, wherein the apparatus is part of a personal computer, a server, a mobile device, a tablet, or an automobile.
